(19) United States
(12) Patent Application Publication
(10) Pub. No.: US 2024/0284600 A1
(43) Pub. Date: Aug. 22, 2024

(54) METHOD FOR PRODUCING WIRING CIRCUIT BOARD

(71) Applicant: NITTO DENKO CORPORATION, Osaka (JP)

(72) Inventors: Hayato TAKAKURA, Osaka (JP); Naoki SHIBATA, Osaka (JP); Rei FUKUI, Osaka (JP); Tomoaki TANAKA, Osaka (JP)

(73) Assignee: NITTO DENKO CORPORATION, Osaka (JP)

(21) Appl. No.: 18/569,093

(22) PCT Filed: May 24, 2022
(86) PCT No.: PCT/JP2022/021222

§ 371 Date: Dec. 11, 2023

(30) Foreign Application Priority Data
Jun. 14, 2021 (JP) 2021-098999
Apr. 4, 2022 (JP) 2022-062685

(51) Int. Cl. H05K 3/10; C25D 5/02; H05K 3/00; H05K 3/18

(52) U.S. Cl. CPC H05K 3/108; C25D 5/022; H05K 3/002; H05K 3/18; H05K 2203/0723

(57) ABSTRACT

A method for producing a wiring circuit board includes a first step of setting a pattern forming region and an opening forming region in a supporting layer; a second step of forming a base insulating layer on the supporting layer at least in the pattern forming region; a third step of forming, by electrolytic plating, a conductive pattern on the base insulating layer in the pattern forming region and a dummy pattern in the opening forming region; and a fourth step of etching at least a portion of the supporting layer in the opening forming region.

### TECHNICAL FIELD

The present invention relates to a method for producing a wiring circuit board.

### BACKGROUND ART

Conventionally, there has been known a method for producing a printed wiring board in which a wiring pattern and a dummy pattern are formed on a support substrate (ref: for example, Patent Document 1 below).

### CITATION LIST

### Patent Document

Patent Document 1: Japanese Unexamined Patent Publication No. 2003-273498

### SUMMARY OF THE INVENTION

### Problem to be Solved by the Invention

There may be a case where an opening is desirably formed in the printed wiring board as described in Patent Document 1. In this case, in the method as described in Patent Document 1, the dummy pattern is formed outside the region where the printed wiring board is formed. Therefore, it is difficult to achieve uniform thickness of the wiring pattern formed near the opening.

The present invention provides a method for producing a wiring circuit board capable of achieving uniform thickness of the conductive pattern formed near the opening.

### Means for Solving the Problem

The present invention [1] includes a method for producing a wiring circuit board, including a first step of setting a pattern forming region and an opening forming region in a supporting layer; a second step of forming an insulating layer on the supporting layer at least in the pattern forming region; a third step of forming, by electrolytic plating, a conductive pattern on the insulating layer in the pattern forming region and a dummy pattern in the opening forming region; and a fourth step of etching at least a portion of the supporting layer in the opening forming region.

According to this method, in the third step, the conductive pattern in the pattern forming region can be formed together with the dummy pattern in the opening forming region.

Therefore, a uniform concentration of metal ions around the conductive pattern can be achieved in the plating solution.

As a result, uniform thickness of the conductive pattern formed near the opening can be achieved.

The present invention [2] includes the method for producing a wiring circuit board described in [1], in which in the second step, the insulating layer is formed in the pattern forming region and the opening forming region, and in the third step, the dummy pattern is formed on the insulating layer in the opening forming region.

According to this method, the insulating layer is formed in the opening forming region, and the dummy pattern can be supported by the insulating layer.

Therefore, even though the entire supporting layer in the opening forming region is etched, the dummy pattern can be supported by the insulating layer.

The present invention [3] includes the method for producing a wiring circuit board described in [2], in which in the first step, a product region including the pattern forming region and the opening forming region and a frame region connected to the product region are further set in the supporting layer, and in the fourth step, the entire supporting layer in the opening forming region is etched to form an opening in the supporting layer, and the supporting layer between the product region and the frame region is etched to form an outer shape of a wiring circuit board along a shape of the product region and to form a frame connected to the wiring circuit board along a shape of the frame region, the method for producing the wiring circuit board further including a fifth step of cutting the wiring circuit board from the frame and cutting the insulating layer in the opening from the wiring circuit board.

According to this method, the dummy pattern can be easily removed by etching the entire supporting layer in the opening forming region to form the opening in the supporting layer and then cutting away the insulating layer in the opening.

The present invention [4] includes the method for producing a wiring circuit board described in [1], in which in the second step, the insulating layer is formed in the pattern forming region and not formed in the opening forming region, and in the third step, the dummy pattern is formed on the supporting layer in the opening forming region.

According to this method, the dummy pattern can be supported by the supporting layer in the opening forming region.

The present invention [5] includes the method for producing a wiring circuit board described in [4], in which in the fourth step, the entire supporting layer in the opening forming region is etched.

According to this method, the dummy pattern can be easily removed by etching the entire supporting layer in the opening forming region.

### Effects of the Invention

According to the method for producing a wiring circuit board of the present invention, even though the conductive pattern is formed near the opening, uniform thickness of the conductive pattern can be achieved.

### BRIEF DESCRIPTION OF THE DRAWINGS

FIG. 1 is a plan view of a wiring circuit board according to an embodiment of the present invention.

FIG. 2 is a cross sectional view taken along line A-A of the wiring circuit board shown in FIG. 1.

FIGS. 3A and 3B graphically illustrate a method for producing the wiring circuit board; FIG. 3A illustrates a step of setting a pattern forming region and an opening forming region in a supporting layer (first step), and FIG. 3B illustrates a step of forming a base insulating layer in the pattern forming region and forming a dummy insulating layer in the opening forming region (second step), which is subsequent to FIG. 3A.

FIG. 4 is a plan view of the supporting layer, base insulating layer, and dummy insulating layer shown in FIG. 3B. FIG. 3B is a cross sectional view taken along line B-B of the supporting layer, base insulating laver, and dummy insulating layer shown in FIG. 4.

FIGS. 5A to 5C graphically illustrate the method for producing the wiring circuit board, which is subsequent to FIG. 3B: FIG. 5A illustrates a step of forming a seed layer on the base insulating layer and the dummy insulating layer, which is subsequent to FIG. 3B, FIG. 5B illustrates a step of attaching a plating resist onto the base insulating layer and dummy insulating layer on which the seed layer has been formed, and exposing the plating resist, which is subsequent to FIG. 5A, and FIG. 5C illustrates a step of developing the exposed plating resist, which is subsequent to FIG. 5B.

FIGS. 6A to 6C graphically illustrate the method for producing the wiring circuit board, which is subsequent to FIG. 5C: FIG. 6A illustrates a step of forming a conductive pattern and a dummy pattern by electrolytic plating (third step), which is subsequent to FIG. 5C, FIG. 6B illustrates a step of peeling off the plating resist, which is subsequent to FIG. 6A, and FIG. 6C illustrates a step of removing the seed layer by etching, which is subsequent to FIG. 6B.

FIG. 7 is a plan view of the supporting layer, base insulating layer, dummy insulating layer, conductive pattern, and dummy pattern shown in FIG. 6C. FIG. 6C is a cross sectional view taken along line C-C of the supporting layer, base insulating layer, dummy insulating layer, conductive pattern, and dummy pattern shown in FIG. 7.

FIGS. 8A and 8B graphically illustrate the method for producing the wiring circuit board, which is subsequent to FIG. 6C: FIG. 8A illustrates a step of forming a cover insulating layer, which is subsequent to FIG. 6C, and FIG. 8B illustrates a step of etching the supporting layer (fourth step), which is subsequent to FIG. 8A.

FIGS. 9A to 9C graphically illustrate a modification (1): FIG. 9A illustrates a step of forming a base insulating layer in the pattern forming region and not forming a dummy insulating layer in the opening forming region (second step), FIG. 9B illustrates a step of forming a dummy pattern on the supporting layer in the opening forming region (third step), which is subsequent to FIG. 9A, and FIG. 9C illustrates a step of etching the supporting layer (fourth step), which is subsequent to FIG. 9B.

FIG. 10 is a plan view of the supporting layer, base insulating layer, dummy insulating layer, conductive pattern, and dummy pattern shown in FIG. 9C. FIG. 9C is a cross sectional view taken along line D-D of the supporting layer, base insulating layer, dummy insulating layer, conductive pattern, and dummy pattern shown in FIG. 10.

FIG. 11 graphically illustrates a modification (3), showing an example in which in the third step, a dummy pattern is formed on the supporting layer in a peripheral portion of the opening forming region, and a dummy pattern 22 is not formed in a central portion of the opening forming region.

FIG. 12 graphically illustrates the modification (3) together with FIG. 11, showing an example in which in the third step, a dummy pattern is formed on the supporting layer in the entire opening forming region.

### DESCRIPTION OF THE EMBODIMENTS

### 1. Wiring Circuit Board

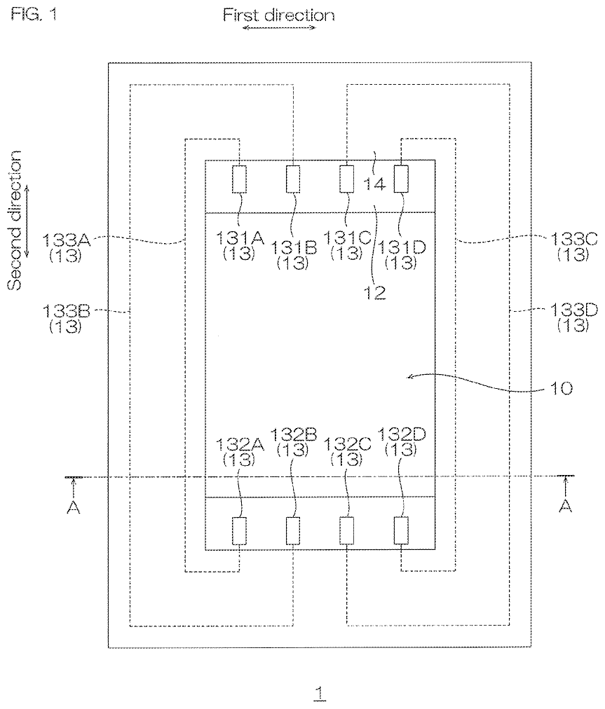

As shown in FIG. 1, a wiring circuit board 1 extends in a first direction and a second direction. In this embodiment, the wiring circuit board 1 has a generally rectangular shape. The shape of the wiring circuit board 1 is not limited. The wiring circuit board 1 has an opening 10.

In this embodiment, the opening 10 is disposed in the center of the wiring circuit board 1 in the first direction and in the second direction. The opening 10 extends in the first and second directions. The opening 10 has a generally rectangular shape. The position of the opening 10 in the wiring circuit board 1 and the shape of the opening 10 are not limited.

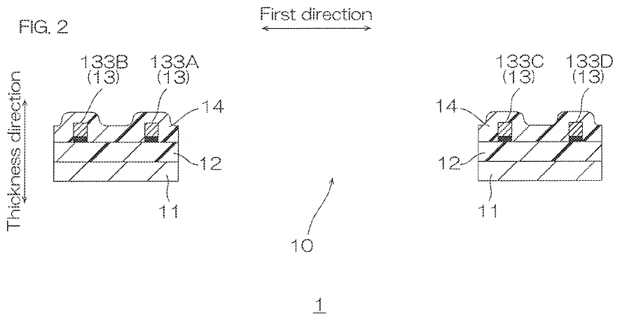

As shown in FIG. 2, the wiring circuit board 1 has a supporting layer 11, a base insulating layer 12 as an example of an insulating layer, a conductive pattern 13, and a cover insulating layer 14.

### (1-1) Supporting Layer

The supporting layer 11 supports the base insulating layer 12, the conductive pattern 13, and the cover insulating layer 14. In this embodiment, the supporting layer 11 is made of metal foil. Examples of the metal include stainless steels and copper alloys.

### (1-2) Base Insulating Layer

The base insulating layer 12 is disposed on the supporting layer 11 in the thickness direction of the wiring circuit board 1. The thickness direction is orthogonal to each of the first direction and the second direction. The base insulating layer 12 is disposed between the supporting layer 11 and the conductive pattern 13 in the thickness direction. The base insulating layer 12 insulates the supporting layer 11 from the conductive pattern 13. The base insulating layer 12 is made of resin. Examples of the resin include polyimide.

### (1-3) Conductive Pattern

The conductive pattern 13 is disposed on the base insulating layer 12 in the thickness direction. The conductive pattern 13 is disposed on the opposite side of the supporting layer 11 with respect to the base insulating layer 12 in the thickness direction. The conductive pattern 13 is disposed around the opening 10. The conductive pattern 13 is made of metal. Examples of the metal include copper. The shape of the conductive pattern 13 is not limited.

In this embodiment, as shown in FIG. 1, the conductive pattern 13 has a plurality of terminals 131A, 131B, 131C, and 131D, a plurality of terminals 132A. 132B, 132C, and 132D, and a plurality of wires 133A, 133B, 133C, and 133D. The number of terminals and the number of wires are not limited.

### (1-3-1) Terminals

In this embodiment, terminals 131A, 131B, 131C, and 131D are disposed at one end of the wiring circuit board 1 in the second direction. The terminals 131A, 131B, 131C, and 131D are disposed on one side in the second direction with respect to the opening 10. The terminals 131A, 131B, 131C, and 131D are spaced apart from each other and are aligned in the first direction. Each of the terminals 131A, 131B. 131C, and 131D has a square land shape.

In this embodiment, the terminals 132A, 132B, 132C, and 132D are disposed at the other end of the wiring circuit board 1 in the second direction. The terminals 131A, 131B, 131C, and 131D are disposed on the other side in the second direction with respect to the opening 10. The terminals 132A, 132B, 132C, and 132D are spaced apart from each other and are aligned in the first direction. Each of the terminals 132A, 132B, 132C, and 132D has a square land shape.

### (1-3-2) Wires

One end of the wire 133A connects to the terminal 131A. The other end of the wire 133A connects to the terminal 132A. The wire 133A electrically connects the terminal 131A to the terminal 132A.

One end of the wire 133B connects to the terminal 131B. The other end of the wire 133B connects to the terminal 132B. The wire 133B electrically connects the terminal 131B to the terminal 132B.

One end of the wire 133C connects to the terminal 131C. The other end of the wire 133C connects to the terminal 132C. The wire 133C electrically connects the terminal 131C to the terminal 132C.

One end of the wire 133D connects to the terminal 131D. The other end of the wire 133D connects to the terminal 132D. The wire 133D electrically connects the terminal 131D to the terminal 132D.

In the following description, each of the plurality of terminals 131A, 131B, 131C, and 131D is referred to as terminal 131, each of the plurality of terminals 132A, 132B, 132C, and 132D is referred to as terminal 132, and each of the plurality of wires 133A, 133B, 133C, and 133D is referred to as wire 133.

### (1-4) Cover Insulating Layer

As shown in FIG. 1, the cover insulating layer 14 covers all the wires 133. The cover insulating layer 14 is disposed on the base insulating layer 12 in the thickness direction. The cover insulating layer 14 does not cover the terminals 131 and 132. The cover insulating layer 14 is made of resin. Examples of the resin include polyimide.

### 2. Method for Producing Wiring Circuit Board

Next, a method for producing the wiring circuit board 1 is described.

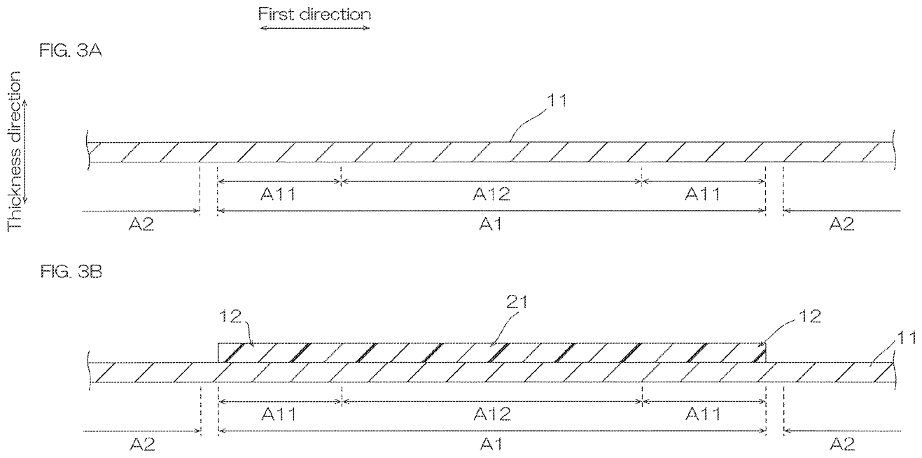

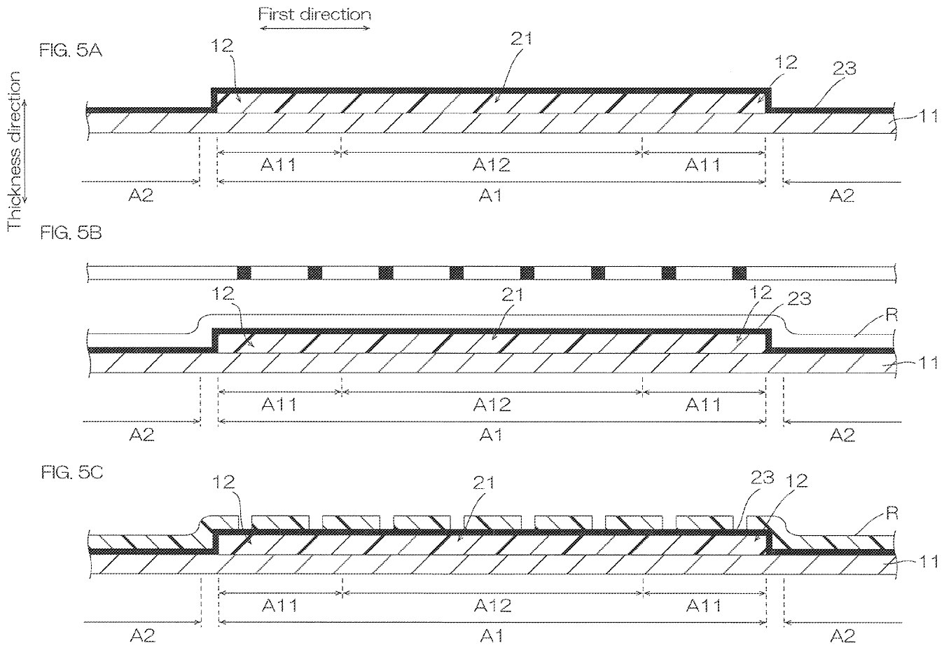

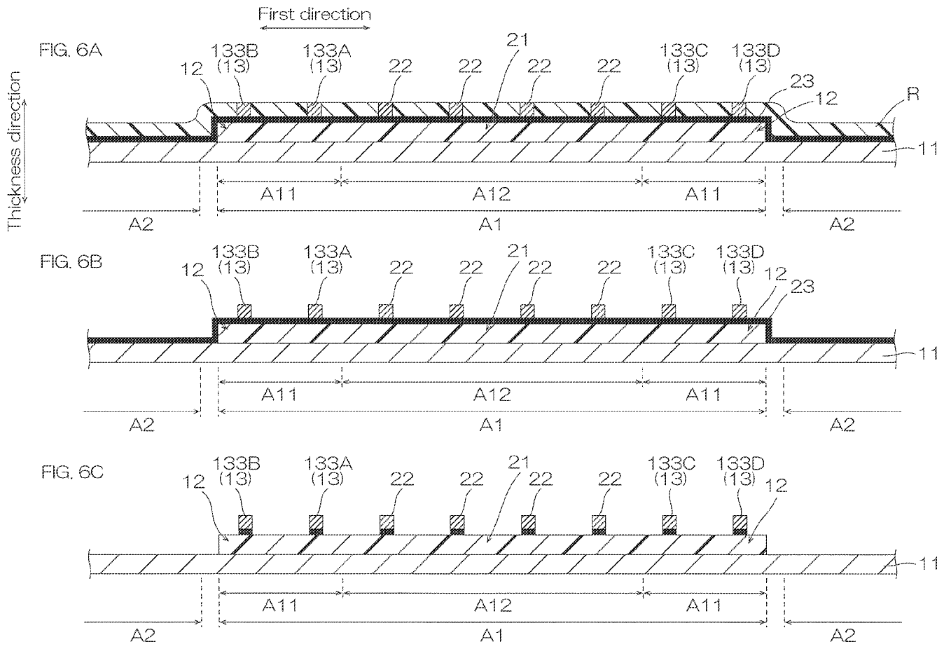

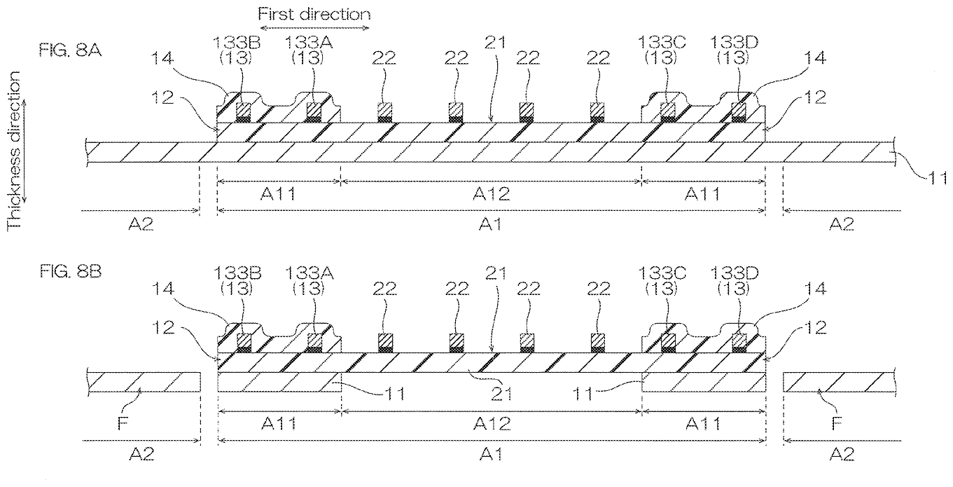

In this embodiment, the wiring circuit board 1 is produced by a semi-additive method. The wiring circuit board 1 may be produced by an additive method. The method for producing the wiring circuit board 1 includes a first step (ref: FIG. 3A), a second step (ref: FIG. 3B), a third step (ref: FIGS. 5A to 6C), a fourth step (ref: FIG. 8B), and a fifth step (ref: FIGS. 8B and 2).

### (1) First Step

As shown in FIG. 3A, in the first step, a product region A1 and a frame region A2 are set in the supporting layer 11. In this embodiment, the supporting layer 11 is a metal foil drawn from a roll of the metal foil.

The above-described wiring circuit board 1 is produced in the product region A1. The product region A1 includes a pattern forming region A11 and an opening forming region A12. In other words, in the first step, the pattern forming region A11 and the opening forming region A12 are set in the supporting layer. The pattern forming region A11 is disposed outside the opening forming region A12. The pattern forming region A11 surrounds the opening forming region A12. The above-described base insulating layer 12, conductive pattern 13, and cover insulating layer 14 are formed in the pattern forming region A11. The above-described opening 10 is formed in the opening forming region A12.

The frame region A2 is set outside the product region A1. The frame region A2 is connected to the product region A1. In the frame region A2, a frame that supports the wiring circuit board 1 is formed.

### (2) Second Step

Next, as shown in FIG. 3B, in the second step, an insulating layer is formed on the supporting layer 11 at least in the pattern forming region A1. In this embodiment, an insulating layer is formed in the pattern forming region A11 and in the opening forming region A12.

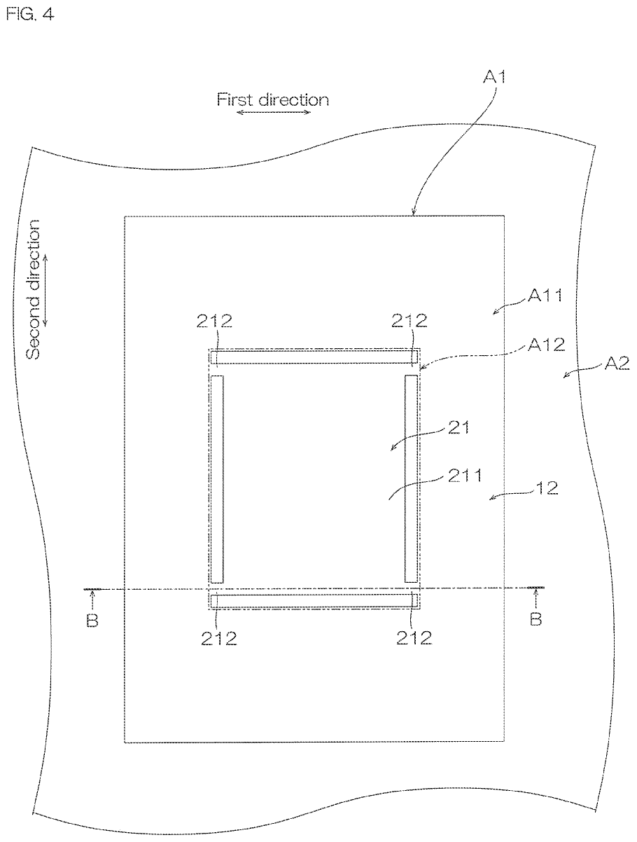

Specifically, as shown in FIG. 4, the above-described base insulating layer 12 is formed in the pattern forming region A11, and the dummy insulating layer 21 is formed in the opening forming region A12.

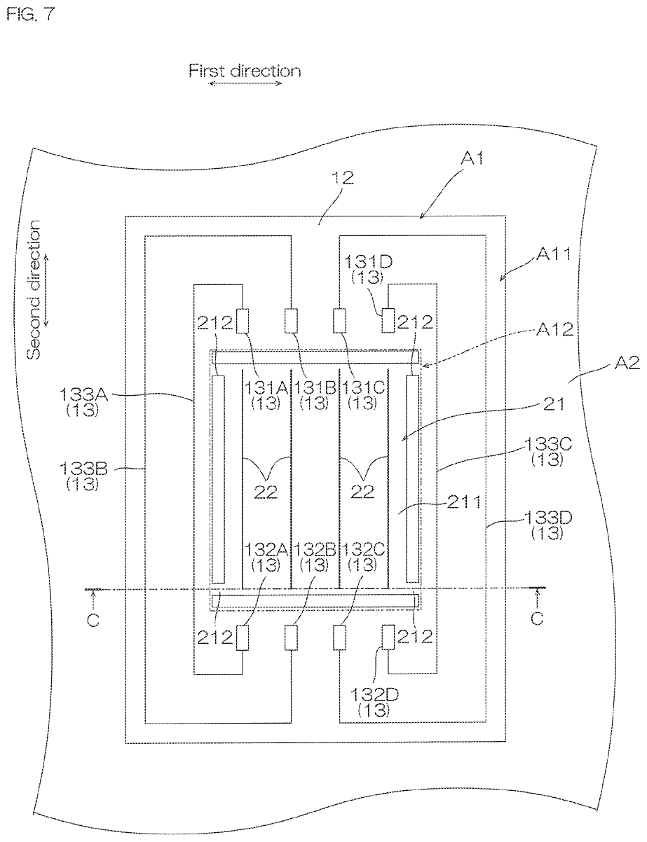

The dummy insulating layer 21 supports a dummy pattern 22 (ref. FIG. 7). The dummy pattern 22 will be described later. The dummy insulating layer 21 has a supporting portion 211 and at least one connecting portion 212. In this embodiment, the dummy insulating layer 21 has a plurality of connecting portions 212.

The supporting portion 211 supports the dummy pattern 22. The supporting portion 211 is disposed so as to be separated from the base insulating layer 12. In this embodiment, the supporting portion 211 has a generally rectangular shape. The shape of the supporting portion 211 is not limited.

Each of the plurality of connecting portions 212 is disposed between the supporting portion 211 and the base insulating layer 12. Each of the plurality of connecting portions 212 is connected to the supporting portion 211 and the base insulating layer 12. Thus, the dummy insulating layer 21 is connected to the base insulating layer 12.

To form the base insulating layer 12 and the dummy insulating layer 21, first, a solution (varnish) of photosensitive resin is applied onto the supporting layer 11 and then dried to form a coated film of photosensitive resin. Next, the coated film of photosensitive resin is exposed to light and developed. In this manner, the base insulating layer 12 and the dummy insulating layer 21 are formed on the supporting layer 11.

### (3) Third Step

Next, as shown in FIGS. 5A to 6C, in the third step, by electrolytic plating, the conductive pattern 13 is formed on the base insulating layer 12 in the pattern forming region A11 and the dummy pattern 22 is formed on the dummy insulating layer 21 in the opening forming region A12.

Specifically, to form the conductive pattern 13 and the dummy pattern 22 by electrolytic plating, first, as shown in FIG. 5A, a seed layer 23 is formed on surfaces of the base insulating layer 12 and dummy insulating layer 21. The seed layer 23 is formed by, for example, sputtering. Examples of a material of the seed layer 23 include chromium, copper, nickel, titanium, and alloys thereof.

Next, as shown in FIG. 5B, a plating resist R is attached onto the base insulating layer 12 and dummy insulating layer 21 on which the seed layer 23 is formed, and a portion where the conductive pattern 13 (ref: FIG. 7) and the dummy pattern 22 (ref. FIG. 7) are formed is shielded from light, and in such a state, the plating resist R is exposed to light.

Next, as shown in FIG. 5C, the exposed plating resist R is developed. This removes the plating resist R from the light-shielded portion, thereby exposing the seed layer 23 in the portion where the conductive pattern 13 and the dummy pattern 22 are formed. The plating resist R in the exposed portion, that is, the portion where the conductive pattern 13 and the dummy pattern 22 are not formed, remains.

Next, as shown in FIG. 6A, the conductive pattern 13 and the dummy pattern 22 are formed on the exposed seed layer 23 by electrolytic plating.

At this time, the conductive pattern 13 is formed together with the dummy pattern 22. Therefore, in the plating solution, a uniform concentration of metal ions around the product region A1 can be achieved, and uniform thickness of the conductive pattern 13 can be achieved.

Next, as shown in FIG. 6B, after electrolytic plating is completed, the plating resist R is peeled off.

Next, as shown in FIG. 6C, the seed layer 23 exposed by peeling the plating resist R is removed by etching.

In this manner, as shown in FIG. 7, the conductive pattern 13 is formed on the base insulating layer 12, and the dummy pattern 22 is formed on the dummy insulating layer 21.

Next, as shown in FIG. 8A, the cover insulating layer 14 is formed on the base insulating layer 12 and the conductive pattern 13 in the same manner as in the formation of the base insulating layer 12. In this embodiment, the cover insulating layer 14 is not formed on the dummy insulating layer 21 and the dummy pattern 22. However, the cover insulating layer 14 may be formed thereon.

### (4) Fourth Step

Next, as shown in FIG. 8B, in the fourth step, the entire supporting layer 11 in the opening forming region A12 is etched to form the opening 10 in the supporting layer 11. In the fourth step, the supporting layer 1I between the product region A1 and the frame region A2 is etched to form an outer shape of the wiring circuit board 1 along the shape of the product region A1 and to form a frame F along the shape of the frame region A2.

To etch the supporting layer 11, a portion that is not to be etched in the supporting layer 11 is covered with an etching resist, and the supporting layer 11 is immersed in an etchant.

Then, the entire supporting layer 11 in the opening forming region A12 is etched to form the opening 10.

At this time, since the dummy pattern 22 is supported by the dummy insulating layer 21, even though the entire supporting layer 11 in the opening forming region A12 is etched, the dummy pattern 22 does not fall off into the etchant. Therefore, even without a device for collecting the dummy pattern 22 that has fallen off in the etchant, the dummy pattern 22 can be provided in the opening forming region A12.

Further, a portion of the supporting layer 11 between the product region A1 and the frame region A2 is etched to form the outer shape of the wiring circuit board 1 and to form the frame F. The frame F is connected to the wiring circuit board 1. In this manner, an assembly sheet having the wiring circuit board 1 with the opening 10, the dummy pattern 22 disposed in the opening 10, and the frame F that supports the wiring circuit board 1 is obtained.

### (5) Fifth Step

Next, as shown in FIG. 2, in the fifth step, the wiring circuit board 1 is cut from the frame F, and the dummy insulating layer 21 in the opening 10 is cut from the wiring circuit board 1.

In this manner, the wiring circuit board 1 is produced.

A method of cutting the wiring circuit board 1 from the frame F. and a method of cutting the dummy insulating layer 21 from the wiring circuit board 1 are not limited. For example, a cutter, die punching, laser processing, or the like is used to cut the connected part between the wiring circuit board 1 and the frame F, and the connecting portions 212 of the dummy insulating layer 21 (ref: FIG. 7), to thereby cut the wiring circuit board 1 from the frame F and cut the dummy insulating layer 21 from the wiring circuit board 1. Traces of the dummy insulating layer 21 cut away may remain on the inner surface of the opening 10 of the wiring circuit board 1.

### 3. Operations and Effects

(1) According to the method for producing the wiring circuit board 1, as shown in FIGS. 6C and 7, by electrolytic plating, the conductive pattern 13 is formed on the base insulating layer 12 in the pattern forming region A11 and the dummy pattern 22 is formed on the dummy insulating layer 21 in the opening forming region A12.

Therefore, the conductive pattern 13 in the pattern forming region A11 can be formed together with the dummy pattern 22 in the opening forming region A12.

In this manner, a uniform concentration of metal ions around the conductive pattern 13 can be achieved in the plating solution.

As a result, uniform thickness of the conductive pattern 13 formed near the opening 10 can be achieved.

(2) According to the method for producing the wiring circuit board 1, as shown in FIG. 8B, the dummy pattern 22 can be supported by the dummy insulating layer 21 in the opening forming region A12.

Therefore, even though the entire supporting layer 11 in the opening forming region A12 is etched, the dummy pattern 22 can be supported by the dummy insulating layer 21.

(3) According to the method for producing the wiring circuit board 1, as shown in FIG. 8B, the entire supporting laver 11 in the opening forming region A12 is etched to form the opening 10, and the supporting layer 11 between the product region A1 and the frame region A2 is etched to form the outer shape of the wiring circuit board 1 and to form the frame F that is connected to the wiring circuit board 1.

Then, as shown in FIG. 2, the wiring circuit board 1 is cut from the frame F, and the dummy insulating layer 21 in the opening 10 is cut from the wiring circuit board 1.

In this manner, the dummy pattern 22 can be easily removed.

### 4. Modification

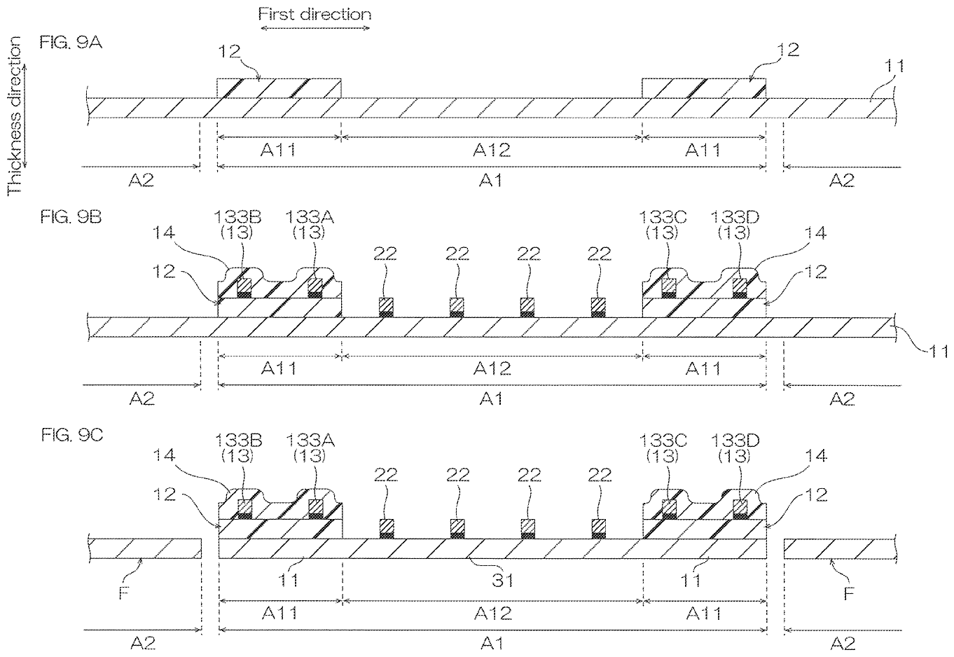

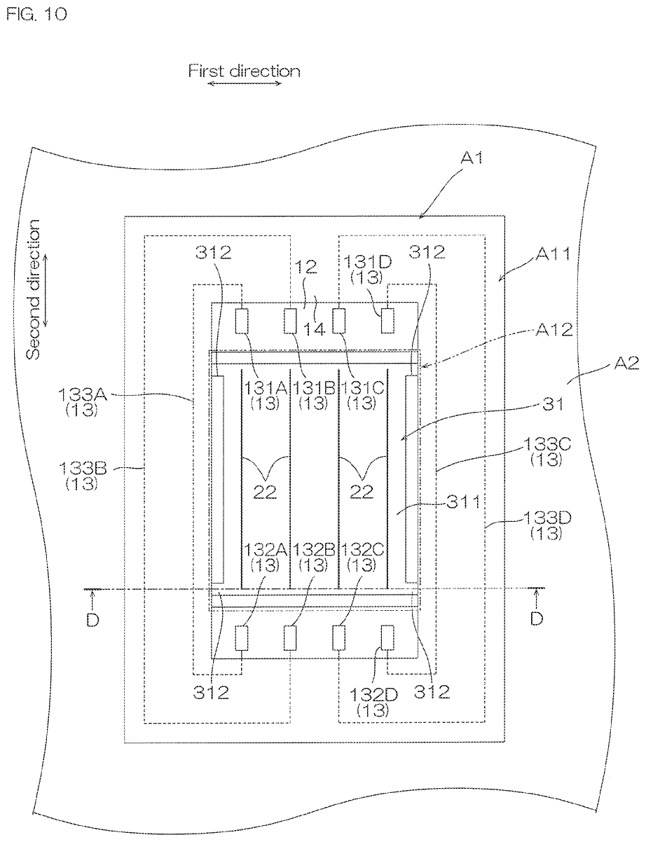

Next, with reference to FIGS. 9A to 10, a modification is described. In the modification, the same reference numerals are provided for the same members as those in the above-described embodiment, and the description thereof is omitted.

(1) As shown in FIG. 9A, in the second step, the base insulating layer 12 is formed in the pattern forming region A11, and the dummy insulating layer 21 may not be formed in the opening forming region A12.

In this case, as shown in FIG. 9B, in the third step, the dummy pattern 22 is formed on the supporting layer 11 in the opening forming region A12.

As shown in FIGS. 9C and 10, in the fourth step, a portion of the supporting layer 11 in the opening forming region A12 is etched. Specifically, a portion of the support layer 11 in the opening forming region A12 is etched along a boundary between the pattern forming region A11 and the opening forming region A12. In this manner, a dummy supporting layer 31 that supports the dummy pattern 22 is formed in the opening forming region A12.

The dummy supporting layer 31 is made of the supporting layer 11 and has the same shape as the above-described dummy insulating layer 21. Specifically, the dummy supporting layer 31 has a supporting portion 311 and at least one connecting portion 312. In this modification, the dummy supporting layer 31 has a plurality of connecting portions 312.

The supporting portion 311 supports the dummy pattern 22. The supporting portion 311 is disposed so as to be separated from the base insulating layer 12. In this embodiment, the supporting portion 311 has a generally rectangular shape. The shape of the supporting portion 311 is not limited.

Each of the plurality of connecting portions 312 is disposed between the supporting portion 311 and the base insulating layer 12. Each of the plurality of connecting portions 312 is connected to the supporting portion 311 and the supporting layer 11 under the base insulating layer 12. Thus, the dummy supporting layer 31 is connected to the supporting layer 11 under the base insulating layer 12.

In this modification, as shown in FIGS. 9C and 2, in the fifth step, the dummy supporting layer 31 is cut from the wiring circuit board 1.

(2) In the fourth step (ref: FIG. 8B) of the above-described embodiment, the dummy supporting layer 31 (ref: FIG. 9C) having the same shape as the dummy insulating layer 21 may be formed by etching a portion of the supporting layer 11 in the opening forming region A12 in the same manner as in the above-described modification (1).

(3) In the fourth step of the above-described modification (1), the entire supporting layer 11 in the opening forming region A12 may be etched without forming the dummy supporting layer 31.

Specifically, as shown in FIG. 9A, in the second step, the base insulating layer 12 is formed in the pattern forming region A11, and the dummy insulating layer 21 is not formed in the opening forming region A12.

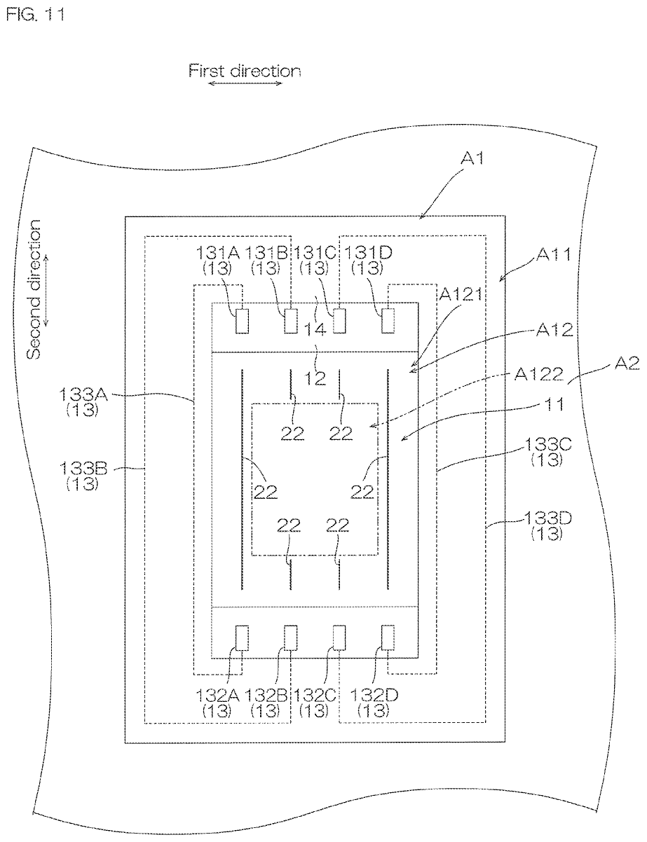

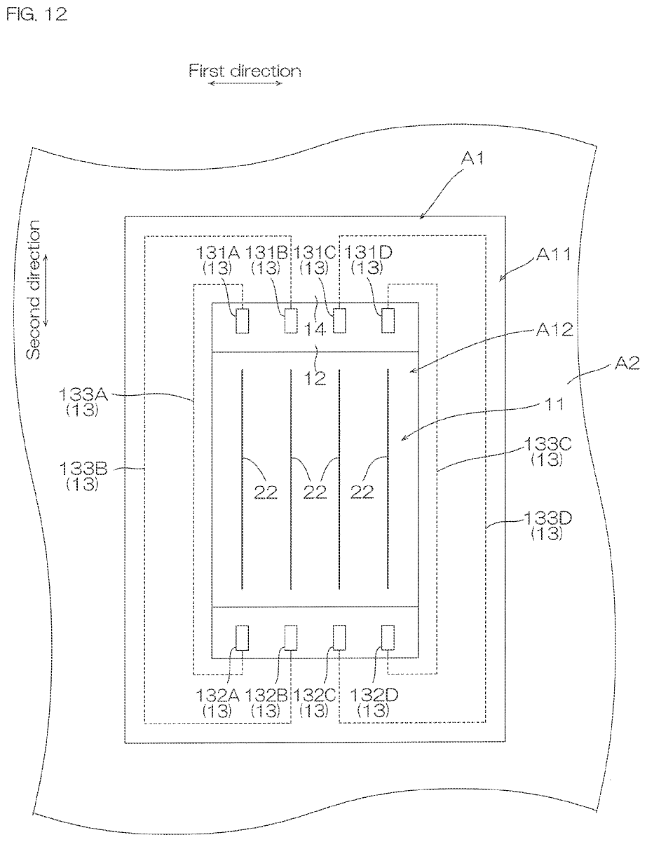

Next, as shown in FIGS. 11 and 12, in the third step, the dummy pattern 22 is formed on the supporting layer 11 in the opening forming region A12.

In FIG. 11, the dummy pattern 22 is formed in a peripheral portion A121 of the opening forming region A12, and the dummy pattern 22 is not formed in a central portion A122 of the opening forming region A12. The peripheral portion A121 is a portion disposed between the central portion A122 and the conductive pattern 13.

In FIG. 12, the dummy pattern 22 is formed in the entire opening forming region A12.

In the fourth step, the entire supporting layer 11 in the opening forming region A12 is etched. In this case, the dummy pattern 22 may fall off into the etchant. When the dummy pattern 22 falls off into the etchant, a device for collecting the dummy pattern 22 that has fallen off in the etchant is preferably used.

According to this modification, the dummy pattern 22 can be easily removed by etching the entire supporting layer 11 in the opening forming region A12.

(4) In the above-described embodiment, as shown in FIG. 11, the dummy pattern 22 is formed in the peripheral portion A121 of the opening forming region A12, and the dummy pattern 22 may not be formed in the central portion A122 of the opening forming region A12.

(5) The dummy pattern 22 may be formed not only in the opening forming region A12, but also in the frame region A2.

While the illustrative embodiments of the present invention are provided in the above description, such is for illustrative purpose only and it is not to be construed restrictively.

Modification and variation of the present invention that will be obvious to those skilled in the art is to be covered by the following claims.

### INDUSTRIAL APPLICABILITY

The method for producing a wiring circuit board according to the present invention is used for the production of wiring circuit boards.

### DESCRIPTION OF REFERENCE NUMERALS

1 wiring circuit board
10 opening
11 supporting layer
12 base insulating layer
13 conductive pattern
21 dummy insulating layer
22 dummy pattern
31 dummy supporting layer
A1 product region
A2 frame region
A11 pattern forming region
A12 opening forming region
F frame

1. A method for producing a wiring circuit board, comprising:
a first step of setting a pattern forming region and an opening forming region in a supporting layer;
a second step of forming an insulating layer on the supporting layer at least in the pattern forming region;
a third step of forming, by electrolytic plating, a conductive pattern on the insulating layer in the pattern forming region and a dummy pattern in the opening forming region; and
a fourth step of etching at least a portion of the supporting layer in the opening forming region.

2. The method for producing a wiring circuit board according to claim 1, wherein
in the second step, the insulating layer is formed in the pattern forming region and the opening forming region, and
in the third step, the dummy pattern is formed on the insulating layer in the opening forming region.

3. The method for producing a wiring circuit board according to claim 2, wherein
in the first step, a product region including the pattern forming region and the opening forming region and a frame region connected to the product region are further set in the supporting layer, and
in the fourth step, the entire supporting layer in the opening forming region is etched to form an opening in the supporting layer, and a portion of the supporting layer between the product region and the frame region is etched to form an outer shape of a wiring circuit board along a shape of the product region and to form a frame connected to the wiring circuit board along a shape of the frame region,
the method for producing the wiring circuit board, further comprising
a fifth step of cutting the wiring circuit board from the frame and cutting the insulating layer in the opening from the wiring circuit board.

4. The method for producing a wiring circuit board according to claim 1, wherein
in the second step, the insulating layer is formed in the pattern forming region and not formed in the opening forming region, and
in the third step, the dummy pattern is formed on the supporting layer in the opening forming region.

5. The method for producing a wiring circuit board according to claim 4, wherein in the fourth step, the entire supporting layer in the opening forming region is etched.
